(19) United States
(12) Patent Application Publication
(10) Pub. No.: US 2018/0097378 A1
(43) Pub. Date: Apr. 5, 2018

(54) LOW-VOLTAGE, HIGH-CURRENT CHARGING WITH OVER-VOLTAGE SENSING

(71) Applicant: FAIRCHILD SEMICONDUCTOR CORPORATION, Sunnyvale, CA (US)

(72) Inventors: Robert A. CARD, Scarborough, ME (US); James A. MEACHAM, II, Gorham, ME (US)

(73) Assignee: FAIRCHILD SEMICONDUCTOR CORPORATION, Sunnyvale, CA (US)

(21) Appl. No.: 15/710,177

(22) Filed: Sep. 20, 2017

Related U.S. Application Data
(60) Provisional application No. 62/402,759, filed on Sep. 30, 2016.
(60) Provisional application No. 62/405,778, filed on Oct. 7, 2016.

(51) Int. Cl. H02J 7/00; G01R 19/165; G01R 31/36

(52) U.S. Cl. CPC H02J 7/0029; G01R 31/3624; G01R 19/16528; H02J 7/007

(57) ABSTRACT

A power converter includes a load detector a processor and a power control block. The load detector is configured to determine a change in a load value of an electronic device coupled to the power converter without receiving a message communicated from the electronic device indicating the change in the load value, and determine if the change in the load value exceeds a threshold value. The processor, in response to determining the change in the load value exceeds the threshold value, is configured to signal the power converter to reduce a voltage. The power control block is configured to reduce the voltage based on the signal.

### RELATED APPLICATIONS

This application claims priority to and the benefit of U.S. Provisional Application No. 62/402,759, entitled, “LOW-VOLTAGE, HIGH-CURRENT CHARGING WITH KELVIN SENSE FROM TRAVEL ADAPTOR TO CELL,” filed Sep. 30, 2016, and claims priority to and the benefit of U.S. Provisional Application No. 62/405,778, entitled, “LOW-VOLTAGE, HIGH CURRENT CHARGING TYPE-C CABLE”, filed Oct. 7, 2016, both of which are incorporated herein by reference in their entireties.

### FIELD

Embodiments relate to detecting a change in a value of a load (e.g., voltage, current and/or resistance while charging an electronic device using a universal serial bus (USB) power converter.

### BACKGROUND

USB Type-C is a USB standard that allows for low-voltage, high-current battery charging and/or electronic device powering applications. A sudden decrease in system load value during high-current charging can cause a sudden increase in bus voltage, which can damage the battery, damage the electronic device and/or trip an over-voltage protection (OVP) device.

### SUMMARY

In at least one general aspect, a power converter includes a load detector a processor and a power control block. The load detector is configured to determine a change in a load value of an electronic device coupled to the power converter without receiving a message communicated from the electronic device indicating the change in the load value, and determine if the change in the load value exceeds a threshold value. The processor, in response to determining the change in the load value exceeds the threshold value, is configured to signal the power converter to reduce a voltage. The power control block is configured to reduce the voltage based on the signal.

In another general aspect, a method includes determining an electronic device is coupled to a power converter via a cable assembly, communicating a desired contact configuration from the power converter to the electronic device, transferring power from the power converter to the electronic device at a voltage and a current, at the power converter, monitoring a change in load value of the electronic device using the desired contact configuration, determining if the change in load value exceeds a threshold value, and in response to determining the change in load value exceeds the threshold value, reducing the voltage at the power converter.

In yet another general aspect, an electronic device a multiplexor and a processor. The multiplexor is configured to switch a contact pair associated with a connector between a normal operational position and a battery cell position, and the processor is configured to receive a message including a desired contact configuration from a power converter coupled to the electronic device via a cable assembly, and instruct the multiplexor to switch between the normal operational position and the battery cell position based on the desired contact configuration.

### BRIEF DESCRIPTION OF THE DRAWINGS

FIG. 1 is a block diagram illustrating a power converter according to at least one example embodiment.

FIGS. 2 and 3 are block diagrams illustrating a system according to at least one example embodiment.

FIG. 4 is a block diagram illustrating a structure of serial interface within a electronic device according to at least one example embodiment.

FIG. 5 is a diagram that illustrates a cross-sectional view of a USB Type-C charging cable according to at least one example embodiment.

FIG. 6 is a diagram that illustrates a cross-sectional view of a USB Type-C charging cable according to at least one example embodiment.

FIG. 7 is a flowchart illustrating a method for preventing an over-voltage condition while charging a device according to at least one example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative positioning of regions and/or structural elements may be reduced or exaggerated for clarity. The use of similar or identical reference numbers in the various drawings is intended to indicate the presence of a similar or identical element or feature.

### DETAILED DESCRIPTION OF THE EMBODIMENTS

An over-voltage condition in a power converter and/or an electronic device can trigger an over-voltage protection (OVP) action. The OVP action can include, for example, termination of a charging operation. Although the OVP action can result in placing the power converter and/or the electronic device in a safe condition (e.g., preventing damage or overheating), the OVP action can be triggered too slowly causing an undesirable user experience. For example, some overheating of the electronic device can occur. Further, triggering of the OVP action (e.g., termination of a charging operation) can cause an undesirable user experience by preventing an expected result (e.g., the battery being charged).

In some implementations, an over-voltage condition can cause damage to the power converter and/or the electronic device. Typically, in a USB TYPE-C system the power converter and the electronic device communicate with each other over a communication channel. If either of the power converter or the electronic device detects an over-voltage condition, a communication is commenced causing the power converter and/or the electronic device to initiate (e.g., trigger) an OVP action (e.g., take action to reduce the voltage) on the power converter and/or the electronic device. The communication can include generating and sending messages as, for example, data packets and/or or digital signals between the electronic device and the power converter. The communication can be over a dedicated communication channel (e.g., configuration channel (CC)).

In some implementations, communications to trigger an OVP action can take a substantial amount of time (e.g., to generate messages), which may be undesirable. Therefore, action to protect the power converter and/or the electronic device may not be fast enough to prevent damage to the power converter and/or the electronic device.

In example embodiments described herein, a power converter can be configured to detect a change in a voltage, current and/or resistance associated with a value of a load (e.g., using a Kelvin sense circuit or a separate pairs of current-carrying terminations and voltage-sensing terminations to measure a value of a load, impedance or resistance) associated with the electronic device without receiving a communication (e.g., a digital communication, a message, a data packet and/or the like) indicating a change (e.g., a change in voltage, current and/or resistance) in a value of a load and/or a communication (e.g., a digital communication, a message, a data packet and/or the like) indicating an OVP from the electronic device. In other words, the power converter can detect an analog voltage, current and/or resistance representing a change in the value of the load without the electronic device generating a message (e.g., indicating an OVP) and communicating the message over the communication channel to the power converter. If the change in the value of the load is up to and/or exceeds a threshold value such that the bus voltage may increase up to and/or exceed an over-voltage threshold, the power converter can be configured to reduce the bus voltage in order to prevent damage to the power converter and/or the electronic device. In other words, a decreasing load (e.g., at the electronic device) can cause voltage to increase. The voltage increase can be caused by less current and/or resistance drop (also known as IR drop) across the cable from the power converter to the electronic device, resulting in more current into the electronic device (e.g., the battery of the electronic device) raising the battery terminal voltage. In some implementations, if the change in the value of the load up to and/or exceeds a threshold value such that the bus voltage may increase up to and/or exceeds an over-voltage threshold, the power converter can be configured to prevent the initiation of an OVP by reducing voltage before the OVP can be initiated.

Further, because the power converter can be configured to detect a change in a voltage, current and/or resistance associated with a load using an analog technique, the power converter can be configured to modify power setting (e.g., voltage and/or current) associated with the power converter to prevent an OVP action from being triggered (e.g., at the power converter and/or the electronic device). As a result, the preventing of the triggering of the OVP action can prevent an undesirable user experience by preventing, for example, terminating the charging of a battery.

While example embodiments may include various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the claims. Like numbers refer to like elements throughout the description of the figures.

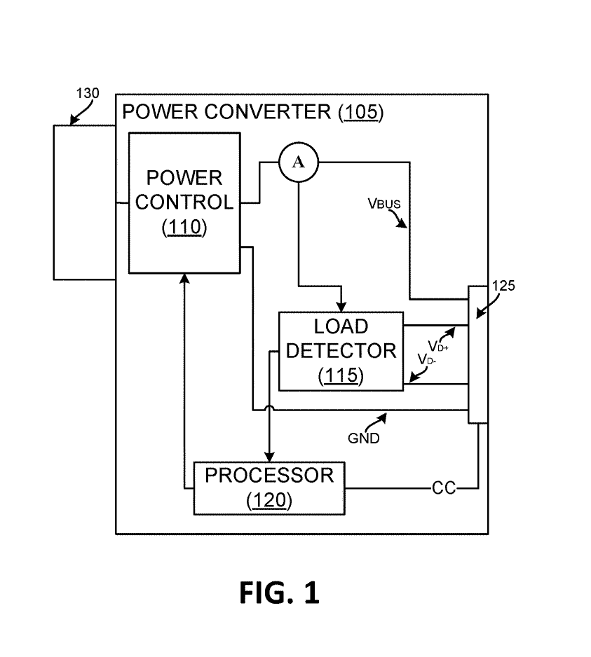

FIG. 1 is a block diagram illustrating a power converter according to at least one example embodiment. As shown in FIG. 1, a power converter 105 includes a power control block 110, a load detector 115, a processor 120, and an interface 125. The power control block 110 can be configured to set a voltage and/or a current output for the power converter 105. For example, the voltage can be set by using a transformer to convert a source voltage (e.g., source voltage from a wall outlet) via plug 130. In an example implementation, the transformer can have a plurality of voltage output settings that can be selected by the power control block 110. The current can be set based on a value of a load (or load value) coupled (e.g., via a cable assembly) to the interface 125. For example, the current can be set based on a current draw of an electronic device (e.g., electronic device 225 described below) coupled to the power converter 105.

The processor 120 can be configured to instruct the power control block 110 regarding the voltage and/or the current settings to use. For example, the processor 120 can receive a message from an electronic device coupled to the interface 125 via a configuration channel (CC). The message can indicate a voltage and/or a current to use for charging a battery associated with the electronic device. The processor 120 can use the voltage and/or current to instruct the power control block 110.

The load detector 115 can be configured to determine a value of a load (e.g., an electronic device being charged by the power converter 105) coupled to the interface 125. The value of the load can be based on a voltage across V_{D+} and V_{D-} and the current A associated with the bus voltage (e.g., the current output of the power converter 105). Therefore, determining the value of the load can be based on an analog measurement and not based on a message received from, for example, an electronic device (e.g., electronic device 225 described below) being charged. Ohm's law can then be used by the load detector 115 to determine the value of the load coupled to the interface 125.

The load detector 115 can be further configured to determine if the value of the load has changed more than a threshold value. For example, the change can be a percent change. The threshold value can be based on a change in bus voltage (V_{bus}) that can cause an OVP condition and/or an over-voltage condition that can cause damage to the power converter 105 and/or damage to the electronic device coupled to the interface 125. In response to determining the value of the load has changed more than a threshold value, the load detector 115 can communicate a signal or message to the processor 120. In response to receiving the signal or message, the processor 120 can instruct the power control block 110 to decrease voltage. For example, the processor 120 can determine a lower voltage based on the change in the value of the load and instruct the power control block 110 to decrease voltage to the lower voltage.

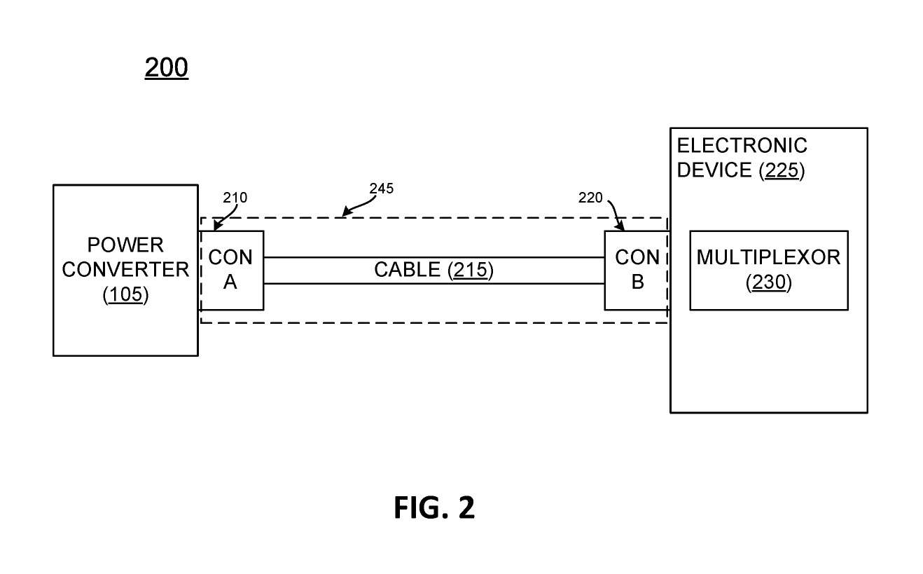

FIGS. 2 and 3 are block diagrams illustrating a system according to at least one example embodiment. As shown in FIG. 2, the system 200 can include the power converter 105 and an electronic device 225. The power converter 105 can be a travel adapter, a charger configured to be plugged into a wall outlet, a power brick, a battery, an electronic device, and the like. The power converter 105 can be configured to provide power (e.g., voltage and/or current) to the electronic device 225 via cable assembly 245. FIG. 3 is a more detailed view of the components of FIG. 2.

The electronic device 225 can be any electronic device or device including a processor and a battery. For example, the electronic device can be any of a mobile phone, computer, laptop, smart watch, and/or the like. The electronic device 225 can be configured for fast (e.g., quick, rapid, and the like) charging based on a USB standard. The electronic device 225 can be configured to draw a fixed and/or variable current and/or voltage. Connector A and connector B can be a standard(s) based connectors (e.g., USB TYPE-C). The power converter 205 has a corresponding interface that connector A can plug into. The electronic device 225 has a corresponding interface that connector B can plug into. The cable 215, connector A and connector B together can be a cable assembly 245.

The electronic device 225 includes a multiplexor 230. The multiplexor 230 can be configured to select (e.g., switch between) a contact pair associated with the connector B between a normal operational position and a battery cell or terminal position. For example, in a first mode of the multiplexor 230 the normal operational position can be selected and in a second mode of the multiplexor 230 the battery cell can be selected.

For example, as shown in FIG. 3, a battery 305 is coupled to bus voltage (V_{bus}) and ground (GND). Further, a processor 310 is communicatively coupled to connector B via a differential pair D+ and D−. Typically, the differential pair is used to provide a communication path between two electronic devices. However, when a power converter (e.g., power converter 105) is used to charge the battery 305, the differential pair D+ and D− is not used. Therefore, in example embodiments described herein, the differential pair D+ and D− can be used as a path over which a voltage drop across the battery can be determined (e.g., by power converter 105). Therefore, the multiplexor 230 can be configured to switch the differential pair D+ and D− associated with the connector B between the processor 310, when operating a communication path between two electronic devices, and the battery 305, when charging the battery using the power converter 105.

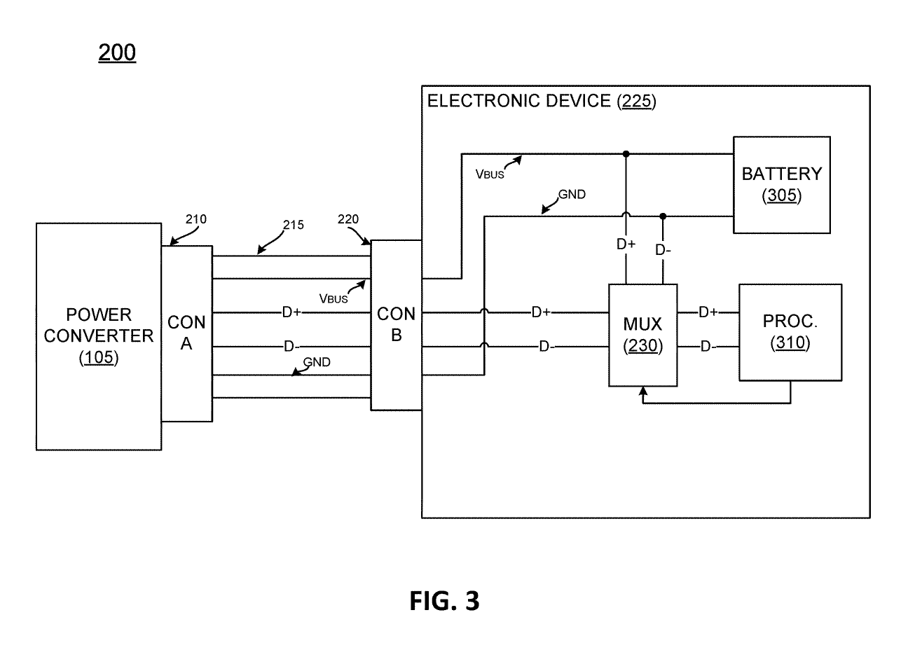

FIG. 4 is a block diagram illustrating a structure of serial interface within an electronic device according to at least one example embodiment. The structure of the serial interface 405 is modified as compared to an interface of the USB-C standard in that serial interface 405 redirects a path in the interface (or from the interface) to the multiplexor 230 instead of directly to a processor (e.g., processor 310). This redirected path allows for implementation of the techniques described herein.

As shown in FIG. 4, the serial interface 405 can include a plurality of contacts (or pins) A1 to A12 and B1 to B12. Contact A1, A12, B1 and B12 can be ground contacts. Contacts A2 and A3 (TX1+, TX1−), B2 and B3 (TX1+, TX1−) can form differential pairs in a high speed transmission (TX or transmit end) line or path. Contacts A10 and A11 (RX2−, RX2+), B10 and B11 (RX1−, RX1+) can form differential pairs in a high speed transmission (RX or receive end) line or path. Contacts A4, A9, B4 and B9 can be bus power (V_{bus}) contacts. Contacts A5 and B5 (CC1, CC2) can form a configuration channel. The configuration channel (CC) is a low speed communication channel used to communicate configuration parameters. For example, CC can be used to detect attachment of USB ports, to establish source and sink roles for devices (e.g., during power transfer), to establish V_{bus} configuration (e.g., voltage and/or current), and the like. Contacts A6, A7, B6 and B7 (D+, D−) can form a differential pair in a transmission line or path. Contacts A8 and B8 can form a channel as a side band use (SBU). SBU is not used in normal USB operations. However, SBU can be used in alternate USB modes. For example, in an alternate USB mode, SBU can be used as a video channel, an audio channel and the like.

The serial interface 405 can be a USB Type-C connector. The USB Type-C connector is a USB connector type that allows for low-voltage, high-current battery charging and/or electronic device powering applications. As shown in FIG. 4, the serial interface 405 can coupled to the multiplexor 230 using contacts A6, A7, B6 and B7 (D+, D−). Although the coupling is via contacts A6, A7, B6 and B7 (D+, D−), other variations are possible. For example, combinations of contacts A2 and A3 (TX1+, TX1−), B2 and B3 (TX1+, TX1−), contacts A10 and A11 (RX2−, RX2+), B10 and B11 (RX1−, RX1+), and contacts A8 and B8 can form a channel as a side band use (SBU) could be used when charging using the power converter 105.

In addition, the configuration channel (CC) can be used as a path to communicate between the power converter 105 and the electronic device 225 (shown in, for example, FIG. 2). The communication can be between the processor 120 and the processor 310 such that the multiplexor 230 can be configured to select a desired contact configuration (e.g., contacts A6, A7, B6 and B7 (D+, D−) as shown).

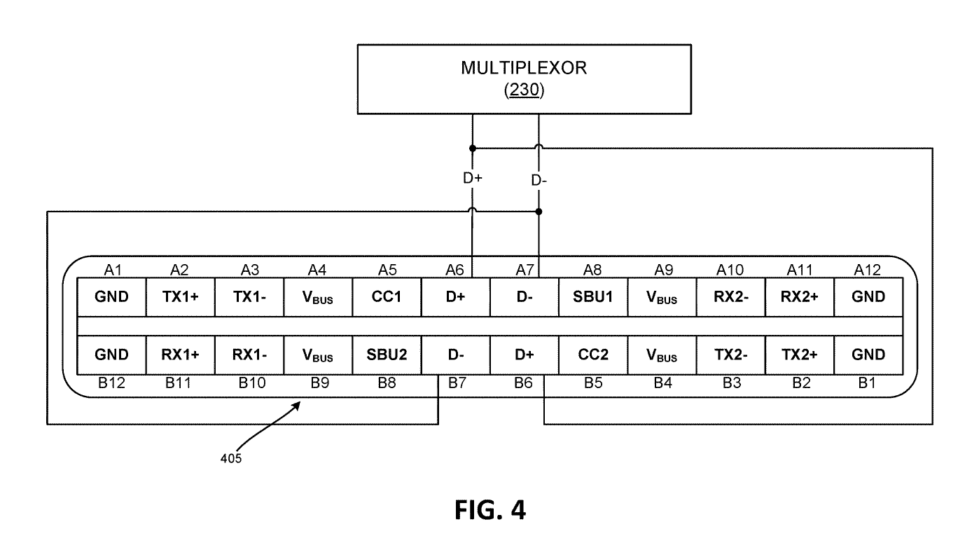

FIG. 5 is a diagram that illustrates a cross-sectional view of a USB Type-C charging cable. As shown in FIG. 5, the USB Type-C charging cable 500 includes a single, braided V_{bus} conductor 510 around a single, insulated, CC wire 505 (e.g., 32-gauge wire). Each single, braided V_{bus} conductor 510 can be insulated from a braided ground shield 520 using an inner insulator 515. The USB Type-C charging cable 500 can be covered with a jacket 525. The USB Type-C charging cable 500 can be implemented as the cable 215.

The USB Type-C charging cable 500 can represent a reduction in size (e.g., OD) over a typical charging cable because the USB Type-C charging cable 500 can have (or approach) a zero gap inside the cross section of the cable and/or within the jacket. In addition to the reduction of empty space, the USB Type-C charging cable 500 can have a reduction in resistance as compared to a typical charging cable because in one or more example implementations, the size (e.g., OD) of the charging cable can be maintained, or increased, while greatly reducing the resistance in the charging cable 500 by more efficiently using the space inside the jacket 525 of the charging cable 500. In other words, the USB Type-C charging cable 500 can have a smaller size (e.g., OD) while maintaining approximately the same resistance as a typical charging cable or the USB Type-C charging cable 500 can have a lower resistance (e.g., larger conductor) while maintaining approximately the same size (e.g., OD) as a typical charging cable. Further, the USB Type-C charging cable 500 can include multiple braided conductors, replacing one or more of the CC wire or the differential or other pairs of wires with one or more braided conductors.

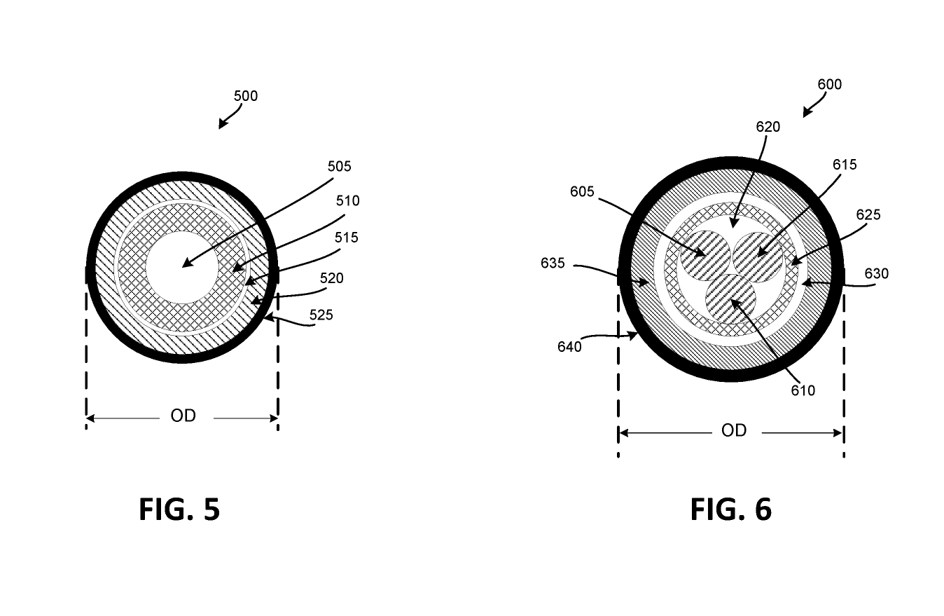

FIG. 6 is a diagram that illustrates a cross-sectional view of a USB Type-C charging cable. As shown in FIG. 6, the USB Type-C charging cable 600 includes a single, braided V_{bus} conductor 625 around an insulated, CC wire 615 (e.g., 32-gauge wire), and a pair of sense wires 605, 610 (e.g., Cell+, Cell−) (e.g., 32-gauge wires). Each single, braided V_{bus} conductor is insulated from a braided ground shield 635 using an inner insulator 630, and covered with a jacket 640. The USB Type-C charging cable 600 can be implemented as the cable 215.

The USB Type-C charging cable 600 can represent a reduction in size (e.g., OD) over a typical charging cable because the USB Type-C charging cable 600 can have (or approach) a zero gap inside the cross section of the cable 600 and/or within the jacket 640. In addition to the reduction of empty space 620, the USB Type-C charging cable 600 can have a reduction in resistance as compared to a typical charging cable because in one or more example implementations, the size (e.g., OD) of the charging cable can be maintained, or increased, while greatly reducing the resistance in the charging cable by more efficiently using the space inside the jacket 640 of the charging cable 600. In other words, the USB Type-C charging cable 600 can have a smaller size (e.g., OD) while maintaining approximately the same resistance as a typical charging cable or the USB Type-C charging cable 600 can have a lower resistance (e.g., larger conductor) while maintaining approximately the same size (e.g., OD) as a typical charging cable. Further, the USB Type-C charging cable 600 can include multiple braided conductors, replacing one or more of the CC wire 615 or the differential (e.g., sense wires 605, 610) or other pairs of wires with one or more braided conductors.

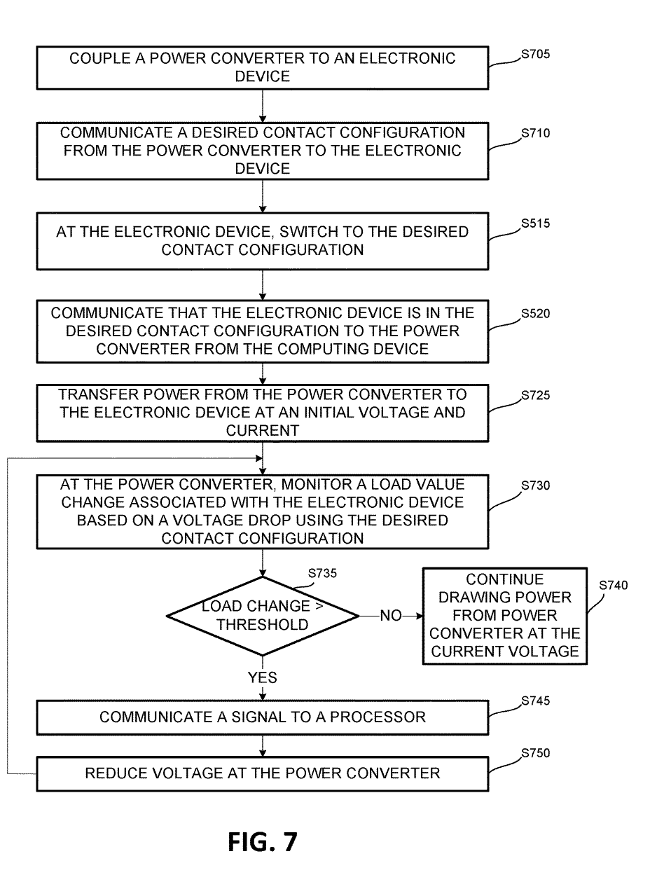

FIG. 7 is a flowchart illustrating a method according to at least one example embodiment. The blocks described with regard to FIG. 7 may be performed in response to the execution of software code stored in a memory and/or a non-transitory computer readable medium (e.g., memory included in electronic device 225 and/or power converter 105) associated with an apparatus (e.g., as shown in FIGS. 1-3 (described above)) and executed by at least one processor (e.g., processor 120, 310) associated with the apparatus. However, alternative embodiments are contemplated such as a system embodied as a special purpose processor. Although the blocks described below are described as being executed by a processor, the blocks are not necessarily executed by a same processor. In other words, at least one processor may execute the blocks described below in connection with FIG. 7.

FIG. 7 is a flowchart illustrating a method for preventing an over-voltage condition while charging an electronic device according to at least one example embodiment. As shown in FIG. 7, in block S705 a power converter is coupled to an electronic device. For example, power converter 105 can be coupled to electronic device 225 using cable assembly 245. Processor 120 and processor 310 can be configured to (and/or receive communications from other components configured to) determine the cable assembly 245 is coupled to the power converter 105 and to the electronic device 225.

In block S710 a desired contact configuration is communicated from the power converter to the electronic device. For example, processor 120 can communicate a message over the configuration channel (CC) to processor 310. The message can indicate that the power converter 105 uses the contacts A6, A7, B6 and B7 (D+, D−) to measure a voltage drop across the battery (e.g., across V_{bus} and ground (GND)). As described above, other contact configurations are within the scope of this disclosure.

In block S715 the electronic device is switched to the desired contact configuration. For example, the processor 310 can communicate a signal to the multiplexor 230. The signal can cause the multiplexor 230 to be configured or switched to cause the contacts A6, A7, B6 and B7 (D+, D−) to be coupled (e.g., via V_{bus} and ground (GND)) to the battery 305.

In block S720 the electronic device being in the desired contact position is communicated from the electronic device to the power converter. For example, processor 310 can communicate a message over the configuration channel (CC) to processor 120. The message can indicate that the electronic device 225 has configured the contacts A6, A7, B6 and B7 (D+, D−) to be coupled to the battery 305 (e.g., coupled to V_{bus} and ground (GND)).

In block S725 power from the power converter is transferred from the power converter to the electronic device at an initial voltage and/or current. For example, the processor 120 can instruct the power control block 110 to output a voltage and/or current based on a requested voltage (e.g., based on battery 305 voltage) and current (e.g., based on a value of the load of the electronic device 225 and/or a charge rate of the battery 305) received from the electronic device 225.

In block S730 at the power converter, a change in the value of the load (or load value) associated with the computing is monitored based on a voltage using the desired contact configuration. For example, the load detector 115 can determine the load value of the electronic device based on a voltage drop across V_{D+} and V_{D-} and the current A associated with the bus voltage (e.g., the current output of the power converter 105). Ohm's law can then be used by the load detector 115 to determine the load value as a resistance.

In block S735 determine if the load value change is greater than a threshold. For example, the change can be a percent change. The threshold value can be based on a change in bus voltage (V_{bus}) that can cause a OVP condition and/or an over-voltage condition that can cause damage to the power converter 105 and/or damage to the electronic device 225. In block S740 in response to determining the load value change is not greater than the threshold, continue drawing power from the power converter at the current voltage.

In block S745 in response to determining the load value change is greater than (or equal to) the threshold, a signal is communicated to a processor of the power converter. For example, the load detector 115 can communicate the signal to the processor 120. The signal can be binary where a 0 indicates the load value change is not greater than the threshold and a 1 indicates the load value change is greater than the threshold or vise versa.

In block S750 voltage at the power converter is reduced. For example, the processor 210 can communicate a message to the power control block 110. The message can be configured to instruct the power control block 110 to reduce voltage. Thus preventing an over-voltage condition. For example, the processor 120 can determine a lower voltage based on the change in the load value and instruct the power control block 110 to decrease voltage to the lower voltage.

Although not shown in FIG. 7 described above, if at any time the power converter 105 is disconnected from the electronic device 225 the processor 120 and/or 310 can terminate the process. In other words, detachment of the cable assembly 245 from the electronic device 225 and/or the power converter 105 can terminate the method described with regard to FIG. 7.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device. Various implementations of the systems and techniques described here can be realized as and/or generally be referred to herein as a circuit, a module, a block, or a system that can combine software and hardware aspects. For example, a module may include the functions/acts/computer program instructions executing on a processor (e.g., a processor formed on a silicon substrate, a GaAs substrate, and the like) or some other programmable data processing apparatus.

Some of the above example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed above, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a storage medium. A processor(s) may perform the necessary tasks.

Specific structural and functional details disclosed herein are merely representative for purposes of describing example embodiments. Example embodiments, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term and/or includes any and all combinations of one or more of the associated listed items.

It will be understood that when an element is referred to as being connected or coupled to another element, it can be directly connected or coupled to the other element or intervening elements may be present. In contrast, when an element is referred to as being directly connected or directly coupled to another element, there are no intervening elements present. Other words used to describe the relationship between elements should be interpreted in a like fashion (e.g., between versus directly between, adjacent versus directly adjacent, etc.).

The terminology used herein is for the purpose of describing particular embodiments only and is not intended to be limiting of example embodiments. As used herein, the singular forms a, an, and the are intended to include the plural forms as well, unless the context clearly indicates otherwise. It will be further understood that the terms comprises, comprising, includes and/or including, when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the above example embodiments and corresponding detailed description are presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the above illustrative embodiments, reference to acts and symbolic representations of operations (e.g., in the form of flowcharts) that may be implemented as program modules or functional processes include routines, programs, objects, components, data structures, etc., that perform particular tasks or implement particular abstract data types and may be described and/or implemented using existing hardware at existing structural elements. Such existing hardware may include one or more Central Processing Units (CPUs), digital signal processors (DSPs), application-specific-integrated-circuits, field programmable gate arrays (FPGAs) computers or the like.

It should be borne in mind, however, that all of these and similar terms are to be associated with the appropriate physical quantities and are merely convenient labels applied to these quantities. Unless specifically stated otherwise, or as is apparent from the discussion, terms such as processing or computing or calculating or determining of displaying or the like, refer to the action and processes of a computer system, or similar electronic device, that manipulates and transforms data represented as physical, electronic quantities within the computer system's registers and memories into other data similarly represented as physical quantities within the computer system memories or registers or other such information storage, transmission or display devices.

Note also that the software implemented aspects of the example embodiments are typically encoded on some form of non-transitory program storage medium or implemented over some type of transmission medium. The program storage medium may be magnetic (e.g., a floppy disk or a hard drive) or optical (e.g., a compact disk read only memory, or CD ROM), and may be read only or random access. Similarly, the transmission medium may be twisted wire pairs, coaxial cable, optical fiber, or some other suitable transmission medium known to the art. The example embodiments not limited by these aspects of any given implementation.

Lastly, it should also be noted that whilst the accompanying claims set out particular combinations of features described herein, the scope of the present disclosure is not limited to the particular combinations hereafter claimed, but instead extends to encompass any combination of features or embodiments herein disclosed irrespective of whether or not that particular combination has been specifically enumerated in the accompanying claims at this time.

1. A power converter comprising:
a load detector configured to:
determine a change in a load value of an electronic device coupled to the power converter without receiving a message communicated from the electronic device indicating the change in the load value, and
determine if the change in the load value exceeds a threshold value;
a processor, in response to determining the change in the load value exceeds the threshold value, configured to signal the power converter to reduce a voltage; and
a power control block configured to reduce the voltage based on the signal.

2. The power converter of claim 1, wherein the load detector is configured to determine the change in the load value of the electronic device based on at least one of a current measurement at the power converter and a voltage measurement at the electronic device.

3. The power converter of claim 1, wherein
the load detector is configured to determine the change in the load value of the electronic device based on a current measurement at the power converter and a voltage measurement at the electronic device, and
the load value is calculated using Ohm's Law.

4. The power converter of claim 1, wherein
the load detector is configured to determine the change in the load value of the electronic device based on a current measurement at the power converter and a voltage measurement at the electronic device, and
the voltage measurement at the electronic device is a voltage drop across a battery of the electronic device sensed via a differential pair of a cable assembly coupling the power converter to the electronic device.

5. The power converter of claim 1, wherein the processor is configured to send a message to the electronic device, the message configured to cause the electronic device to switch a contact pair from a normal operational position to a battery cell position.

6. The power converter of claim 1, wherein
the processor is configured to determine a lower voltage based on the change in the load value, and
instruct the power control block to reduce the voltage to the lower voltage.

7. The power converter of claim 1, wherein the threshold value is based on a change in a load voltage that causes an over-voltage protection (OVP) condition.

8. The power converter of claim 1, wherein the threshold value is based on an over-voltage condition that causes damage to the electronic device coupled to the power converter.

9. The power converter of claim 1, wherein
the power converter is coupled to the electronic device using a cable assembly including a cable having a single, braided VBUS conductor around a single, insulated, CC wire, and
the single, braided VBUS conductor is insulated from a braided ground shield using an inner insulator.

10. A method comprising:
determining an electronic device is coupled to a power converter via a cable assembly;
communicating a desired contact configuration from the power converter to the electronic device;
transferring power from the power converter to the electronic device at a voltage and a current;
at the power converter, monitoring a change in load value of the electronic device using the desired contact configuration;
determining if the change in load value exceeds a threshold value; and
in response to determining the change in load value exceeds the threshold value, reducing the voltage at the power converter.

11. The method of claim 10, wherein the change in the load value of the electronic device is based on at least one of:
a current measurement at the power converter,
a voltage measurement at the power converter, and
a voltage measurement at the electronic device.

12. The method of claim 10, wherein
the change in the load value of the electronic device is based on a current measurement at the power converter and a voltage measurement at the electronic device, and
the load value is calculated using Ohm's Law.

13. The method of claim 10, wherein
the change in the load value of the electronic device is based on a current measurement at the power converter and a voltage measurement at the electronic device,
the voltage measurement at the electronic device is a voltage drop across a battery of the electronic device sensed via a differential pair of the cable assembly coupling the power converter to the electronic device, and
the desired contact configuration indicates the differential pair.

14. The method of claim 10, wherein reducing the voltage at the power converter includes:
determining a lower voltage based on the change in the load value, and
reducing the voltage to the lower voltage.

15. The method of claim 10, wherein the threshold value is based on a change in a bus voltage that causes an over-voltage protection (OVP) condition.

16. The method of claim 10, wherein the threshold value is based on an over-voltage condition that causes damage to the electronic device.

17. The method of claim 10, wherein the change in the load value is a percent change in the load value.

18. An electronic device comprising:
a multiplexor configured to switch a contact pair associated with a connector between a normal operational position and a battery cell position; and
a processor configured to:
receive a message including a desired contact configuration from a power converter coupled to the electronic device via a cable assembly, and
instruct the multiplexor to switch between the normal operational position and the battery cell position based on the desired contact configuration.

19. The electronic device of claim 18, wherein the battery cell position is configured to enable a voltage drop across a battery of the electronic device to be measured by the power converter via a differential pair of the cable assembly.

20. The electronic device of claim 18, wherein the battery cell position is configured to electrically couple a differential pair of the cable assembly to a bus voltage terminal and a ground terminal of a battery of the electronic device.
